(19) United States
(12) Patent Application Publication
(10) Pub. No.: US 2014/0252456 A1
(43) Pub. Date: Sep. 11, 2014

(54) SEMICONDUCTOR DEVICE AND ITS MANUFACTURING METHOD

(71) Applicant: Silergy Semiconductor Technology (Hangzhou) LTD, Hangzhou (CN)

(72) Inventor: Zhongping Liao, Hangzhou (CN)

(73) Assignee: Silergy Semiconductor Technology (Hangzhou) LTD, Hangzhou (CN)

(21) Appl. No.: 14/173,133

(22) Filed: Feb. 5, 2014

(30) Foreign Application Priority Data
Mar. 7, 2013 (CN) 201310073310.1

(51) Int. Cl. H01L 29/10; H01L 29/66; H01L 29/78

(52) U.S. Cl. CPC H01L 29/105; H01L 29/7802; H01L 29/66712
USPC 257/329; 438/268

(57) ABSTRACT

In one embodiment, a semiconductor device can include: (i) a first doped pillar region having a doping concentration that sequentially increases from bottom to top in a vertical direction; (ii) second doped pillar regions arranged on either side of the first doped pillar region in a horizontal direction; and (iii) where sidewalls of the second doped pillar regions form sides of an inverted trapezoidal structure.

### RELATED APPLICATIONS

This application claims the benefit of Chinese Patent Application No. 201310073310.1, filed on Mar. 7, 2013, which is incorporated herein by reference in its entirety.

### FIELD OF THE INVENTION

The present invention relates to the field of semiconductor devices, and more particularly to a semiconductor device with pillar regions, as well as a method of making such a device.

### BACKGROUND

A switched-mode power supply (SMPS), or a “switching” power supply, can include a power stage circuit and a control circuit. When there is an input voltage, the control circuit can consider internal parameters and external load changes, and may regulate the on/off times of the switch system in the power stage circuit. In this way, the output voltage and/or the output current of the switching power supply can be maintained as substantially constant. Therefore, the selection and design of the particular control circuitry and approach is very important to the overall performance of the switching power supply. Thus, using different detection signals and/or control circuits can result in different control effects on power supply performance.

### SUMMARY

In one embodiment, a semiconductor device can include: (i) a first doped pillar region having a doping concentration that sequentially increases from bottom to top in a vertical direction; (ii) second doped pillar regions arranged on either side of the first doped pillar region in a horizontal direction; and (iii) where sidewalls of the second doped pillar regions form sides of an inverted trapezoidal structure.

In one embodiment, a method of making a semiconductor device can include: (i) forming a first doped pillar region having a doping concentration that sequentially increases from bottom to top in a vertical direction; (ii) forming an inverted trapezoidal trench structure; and (iii) forming second doped pillar regions by injecting filler with dopant into the inverted trapezoidal trench structure, where the first doped pillar region and the second doped pillar regions are alternately arranged in a horizontal direction.

Embodiments of the present invention can provide several advantages over conventional approaches, as may become readily apparent from the detailed description of preferred embodiments below.

### BRIEF DESCRIPTION OF THE DRAWINGS

FIG. 1 is a cross-section diagram of an example semiconductor device with a super-junction structure.

FIG. 2A is a diagram of example repetitive pattern extension and injection processes.

FIG. 2B is a diagram of an example diffusion formed semiconductor device with a super-junction structure, after annealing the process as shown in FIG. 2A.

FIG. 3 is a diagram of an example P pillar region in a semiconductor device formed by a trench-refill process.

FIG. 4 is a flow diagram of an example method of making a semiconductor device, in accordance with embodiments of the present invention.

FIG. 5 is a diagram of an example semiconductor device in accordance with embodiments of the present invention.

FIG. 6 is an example horizontal section structure diagram corresponding to the semiconductor device of FIG. 5.

FIG. 7 is a flow diagram of another example method of making a semiconductor device, in accordance with embodiments of the present invention.

FIGS. 8A and 8B are gradient diagrams of an example doping concentration for an extension structure of the example shown in FIG. 5.

FIG. 9 is a diagram of another example semiconductor device in accordance with embodiments of the present invention.

FIG. 10 is a schematic diagram of an example synchronous switching voltage regulator, in accordance with embodiments of the present invention.

### DETAILED DESCRIPTION

Reference may now be made in detail to particular embodiments of the invention, examples of which are illustrated in the accompanying drawings. While the invention may be described in conjunction with the preferred embodiments, it may be understood that they are not intended to limit the invention to these embodiments. On the contrary, the invention is intended to cover alternatives, modifications and equivalents that may be included within the spirit and scope of the invention as defined by the appended claims. Furthermore, in the following detailed description of the present invention, numerous specific details are set forth in order to provide a thorough understanding of the present invention. However, it may be readily apparent to one skilled in the art that the present invention may be practiced without these specific details. In other instances, well-known methods, procedures, processes, components, structures, and circuits have not been described in detail so as not to unnecessarily obscure aspects of the present invention.

A power device (e.g., a metal oxide semiconductor field-effect transistor [MOSFET]) can be utilized in a power supply or regulator (e.g., a switching voltage regulator). Power losses through the power device or transistor can be reduced by reducing the conductive resistance of the MOSFET device. Breakdown or withstand voltage can represent a break down resistant ability of the MOSFET device under a reverse voltage condition. As the conductive resistance exponentially rises along with increases in the breakdown voltage, a “super-junction” MOSFET can be employed as the power transistor to reduce the conductive resistance while also improving the withstand voltage.

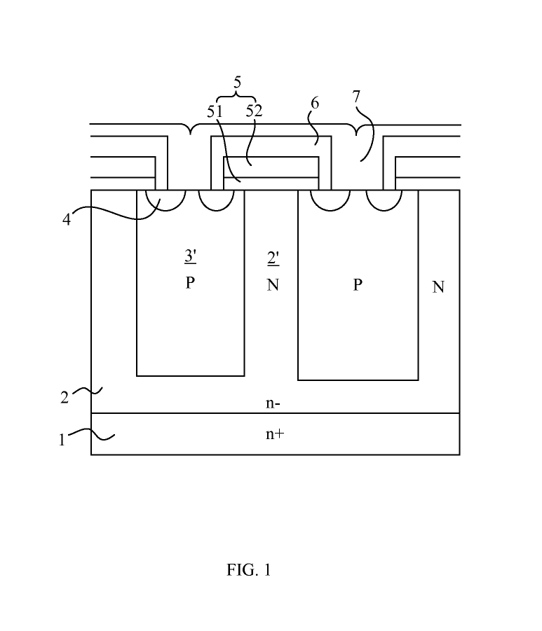

Referring now to FIG. 1, shown is a cross-section diagram of an example semiconductor device with a super-junction structure. In this example, a super-junction power MOSFET can include alternately arranged P “pillar” regions 3′ and N pillar regions 2′ in the active region of the power MOSFET. This can form a PN pillar structure in, and including, n- (lightly doped n-type) “extension” layer 2, which is on n+(heavily doped n-type) semiconductor substrate 1. Also, the super-junction power MOSFET above n-extension layer 2 can include gate stack 5, metal layer 6 covering gate stack 5, and oxide layer 7 on a surface of n-extension layer 2. For example, gate stack 5 can include gate oxide layer 51 and gate 52 (e.g., polysilicon).

For a uniformly doped n-extension layer 2, P pillar regions and N pillar regions that are alternately arranged in the power MOSFET can be in an ideal charge-balance state. For example, C_{P}W_{P}=C_{N}W_{N}, where C_{P} and C_{N} can respectively represent doping concentrations of P pillar regions and N pillar regions, while W_{P} and W_{N} can respectively represent widths of the pillars corresponding to the particular doping concentrations. When the PN pillar structure is in a reverse blocking state (e.g., a reverse biased diode), these regions can be mutually depleted under this reverse voltage condition, which may reduce the electric field across the junction and improve the withstand voltage of the device.

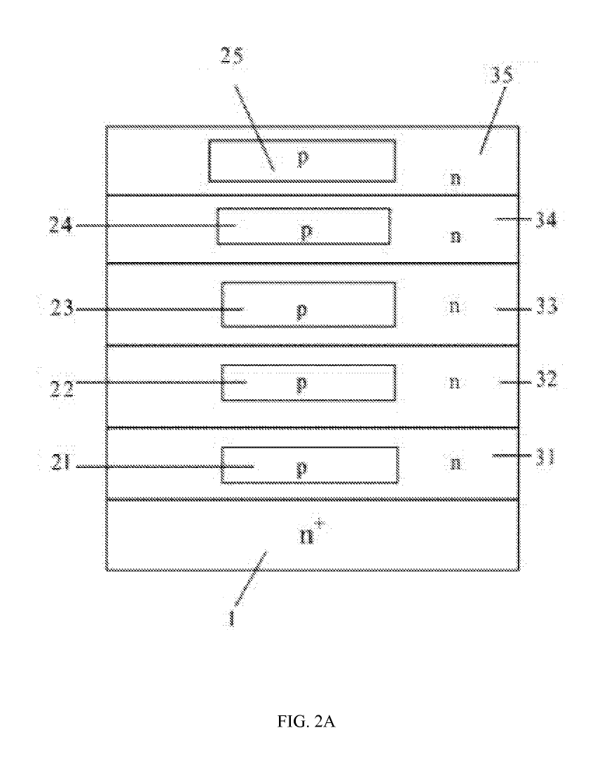

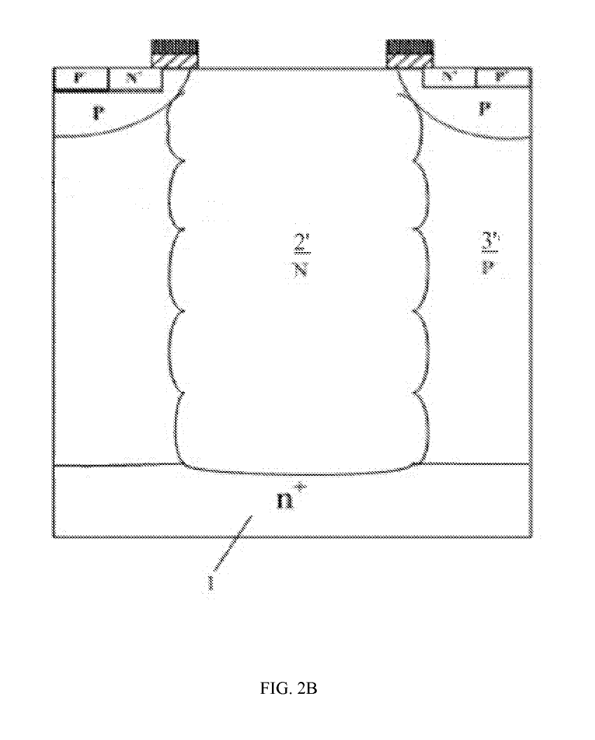

Referring now to FIG. 2A, shown is a diagram of example repetitive pattern of extension and injection processes. In some cases, this type of process can make it relatively difficult to obtain a high performance super-junction power MOSFET. A common super-junction structure can be made by forming n-extension layer 3x (e.g., 31, 32, 33, 34, and 35) and ion implantation region 2x (e.g., 21, 22, 23, 24, and 25) through repeated extension and injection, where X can represent the number of extensions or ion implantation regions.

Referring now to FIG. 2B, shown is a diagram of an example diffusion formed semiconductor device with a super-junction structure, after annealing the process as shown in FIG. 2A. P pillar regions 3′ and N pillar regions 2′ can be formed through one or more such annealing or high temperature processes. The higher the withstand voltage of the power MOSFET, the greater the depth of longitudinal P pillar regions 3′ and N pillar regions 2′. Thus, the extension injection times may be increased to improve the breakdown voltage, which may increase process complexity and product costs in producing the relatively deep P pillar regions 3′ and N pillar regions 2′. In addition, it may be difficult with this approach to form a relatively narrow strip shape (e.g., a narrow strip shape for N pillar region 2′), and to reduce the conductive resistance.

In order to reduce process complexity and product costs, as well as to obtain a high performance super-junction power MOSFET, a super-junction structure can also employ a trench-refill process in particular embodiments. In this process (see, e.g., FIG. 1), n+semiconductor substrate 1 can be formed, and n-extension layer 2 can be formed on n+semiconductor substrate 1. The trench structure can be etched in n-extension layer 2, and p-type silicon can be filled in the trench structure to form a P pillar.

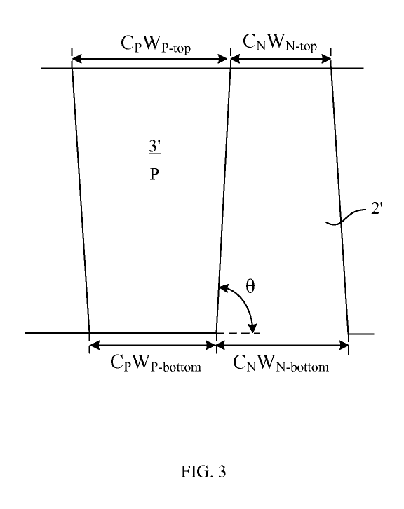

However, to ensure that p-type silicon successfully fills the trench, the trench may have a certain or predetermined angle, as shown in FIG. 3. In FIG. 3, an example P pillar region in a semiconductor device formed by a trench-refill process may have predetermined angle . For example, by using a trench bevel, the vertical section structure or sidewalls of P pillar region 3′ can form an inverted trapezoidal shape (e.g., wide at the top and narrow at the bottom) with top and bottom horizontal surfaces or lines.

Doping concentrations of p-type dopants at the top and bottom surfaces of P pillar region 3′ can respectively be C_{P}W_{P-top} and C_{P}W_{P-bottom}. Doping concentrations of n-type dopants at the top and bottom surfaces of N pillar region 2′ can respectively be C_{N}W_{N-top} and C_{N}W_{N-botton}. Because of the trench bevel or predetermined angle, the upper doping concentration of P pillar region 3′ can be relatively high, while the bottom doping concentration can be relatively low. Also, the upper doping concentration of N pillar region 2′ can be relatively low, while the bottom doping concentration can be relatively high. Thus, C_{P}W_{P-top}>C_{N}W_{N-top}, C_{P}W_{P-bottom}, and C_{N}W_{N-bottom}. As a result, the charge at the top and bottom surfaces of the PN pillar structure may not be balanced in this particular structure.

In one embodiment, a method of making a semiconductor device can include: (i) forming a first doped pillar region having a doping concentration that sequentially increases from bottom to top in a vertical direction; (ii) forming an inverted trapezoidal trench structure; and (iii) forming second doped pillar regions by injecting filler with dopant into the inverted trapezoidal trench structure, where the first doped pillar region and the second doped pillar regions are alternately arranged in a horizontal direction.

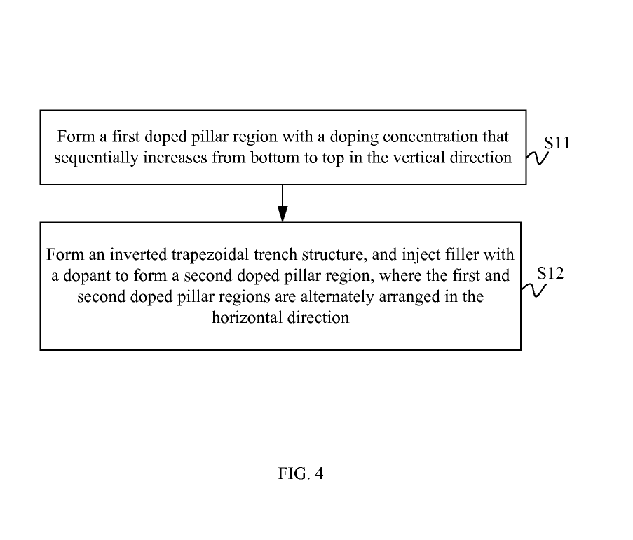

Referring now to FIG. 4, shown is a flow diagram of an example method of making a semiconductor device, in accordance with embodiments of the present invention. At S11, a first doped pillar region can be formed. For example, the doping concentration of the first doped pillar region can sequentially increase from bottom to top of the structure in the vertical direction. At S12, an inverted trapezoidal trench structure can be formed. Also, filler with dopant can be injected into the trench structure to form a second doped pillar region. For example, the first doped pillar region and the second doped pillar region can be alternately arranged in the horizontal direction.

In one embodiment, a semiconductor device can include: (i) a first doped pillar region having a doping concentration that sequentially increases from bottom to top in a vertical direction; (ii) second doped pillar regions arranged on either side of the first doped pillar region in a horizontal direction; and (iii) where sidewalls of the second doped pillar regions form sides of an inverted trapezoidal structure.

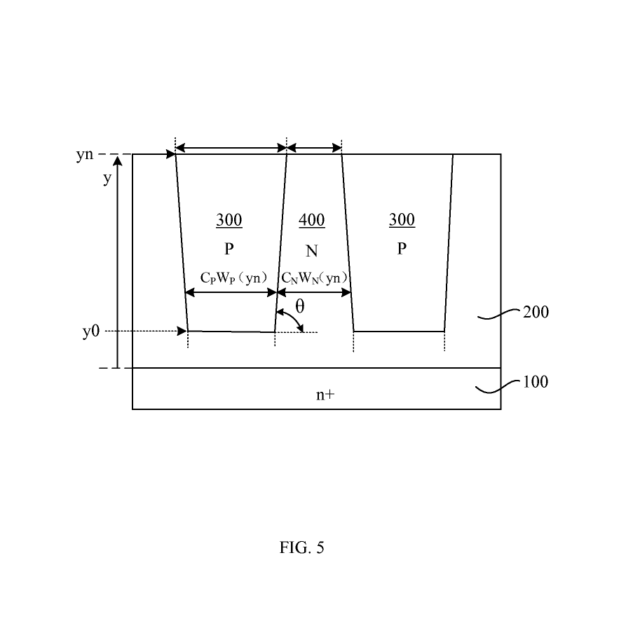

Referring now to FIG. 5, shown is a diagram of an example semiconductor device in accordance with embodiments of the present invention. Doped pillar region 400 with a doping concentration that sequentially increases from bottom to top in the vertical (e.g., the “y”) direction or dimension can be formed. The inverted trapezoidal trench structure can be formed (e.g., by etching), and injected with a filler with dopant to form doped pillar regions 300. The sidewalls of pillar region 300 can be sides of the inverted trapezoidal structure shape.

The dopant type of the filler material can be opposite to that of doped pillar region 400. For example, if the dopant of doped pillar region 400 is p-type, the dopant of the filler can be n-type. On the contrary, if the dopant of doped pillar region 400 is n-type, the dopant of the filler can be p-type. In one particular example, the dopant of the filler is p-type silicon. The super-junction structure can be formed by adjacent doped pillar region 400 and doped pillar region 300.

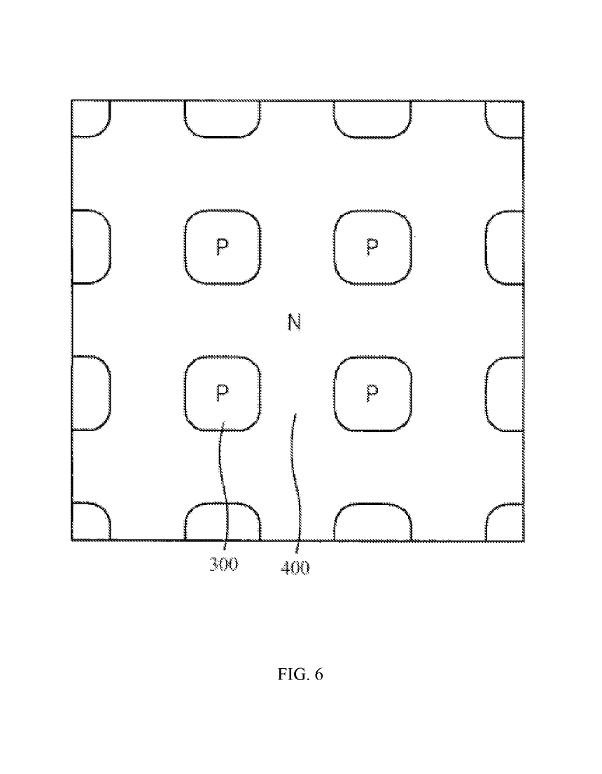

Referring now to FIG. 6, shown is an example horizontal section structure diagram corresponding to the semiconductor device of FIG. 5. Doped pillar regions 300 and doped pillar region 400 can form a horizontal surface structure. For example, the horizontal surface structure can be a strip structure, a circular structure, or a cellular structure. In the cellular structure example, doped pillar structure 400 can surround doped pillar structure 300, as shown. Of course, those skilled in the art will recognize that a wide variety of horizontal surface structures can be supported in particular embodiments.

Referring back to FIG. 5, since the doping concentration of doped pillar region 400 can sequentially increase from bottom to top in the vertical direction, the problem of the upper surface doping concentration being relatively low, while the bottom doping concentration is relatively high, can be avoided. Thus, the super-junction formed by doped pillar region 400 and doped pillar regions 300 can achieve charge-balance at every depth (e.g., each “y” point) of the structure (e.g., that ranges from y0 to yn). In this way, a higher breakdown voltage of the power device formed therefrom can be obtained for a given doping concentration.

Thus in particular embodiments, a semiconductor device can include doped pillar region 400 and doped pillar regions 300 alternately arranged in the horizontal direction. For example, the doping concentration of doped pillar region 400 can sequentially increase from bottom to top in the vertical (e.g., y) direction, and an inverted trapezoidal structure that includes the sidewalls of doped pillar region 300 can be formed.

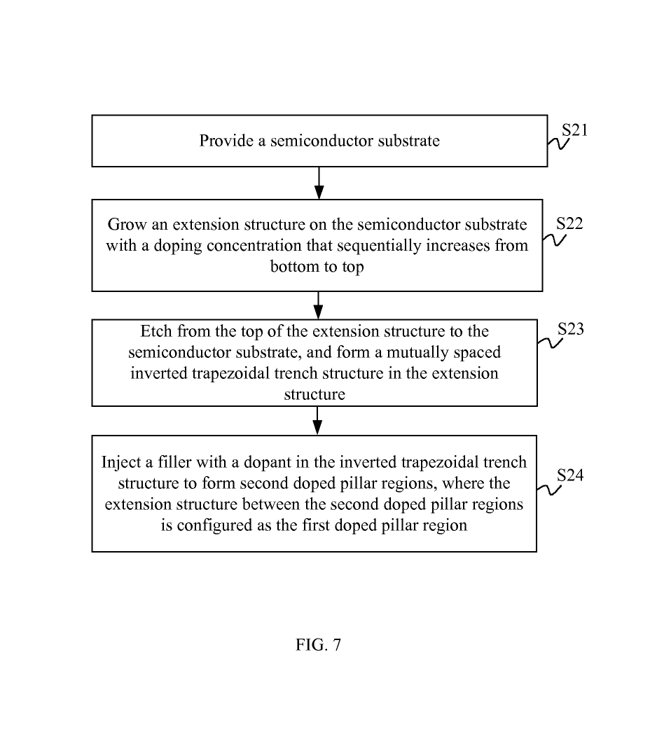

Referring now to FIG. 7, shown is a flow diagram of another example method of making a semiconductor device, in accordance with embodiments of the present invention. At S21, a semiconductor substrate (e.g., n+substrate 100) can be provided. At S22, an extension structure can be grown (e.g., epitaxially) on the semiconductor substrate. Further, the doping concentration of the extension structure can sequentially increase from bottom to top in the vertical or “y” direction of the structure.

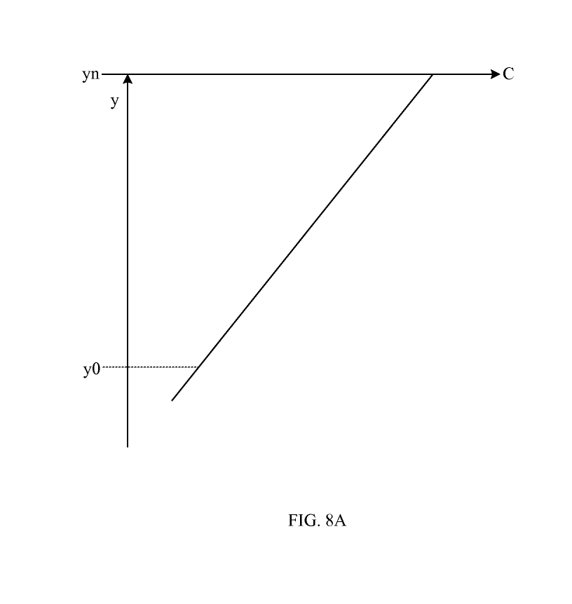

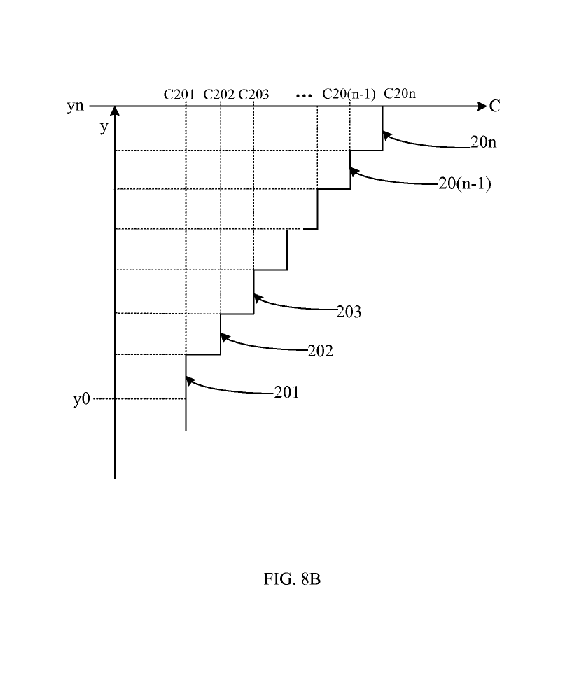

The doping concentration of the extension structure can be represented as shown FIGS. 8A and 8B, with gradient diagrams of an example doping concentration when employing a monolayer or a multilayer extension structure. A monolayer extension structure with a doping concentration as shown in FIG. 8A, or repeatedly or incrementally growing a multilayer extension structure with a doping concentration as shown in FIG. 8B, can be grown on semiconductor substrate 100.

In FIG. 8A, if extension structure 200 is monolayer structure with the doping concentration sequentially increasing from bottom to top in the vertical (y) direction, the extension of the monolayer can be formed by a single extension growth on the semiconductor substrate. As shown, “sequentially increasing” can be a monotonic increase in the doping concentration in going from the bottom (e.g., y0) to the top (e.g., yn) of extension structure 200 that is, e.g., to be used for doped pillar region 400.

In FIG. 8B, extension structure 200 may not be a monolayer structure, but rather can include a plurality of extension layers 201, 202, 203 . . . 20(n−1), 20n (e.g., n is an integer greater than 1). For example, the doping concentration of each of the extension layers 20n within the multilayer extension structure can be uniformly distributed, and may sequentially increase from bottom to top. That is, each extension layer in the multilayer extension structure can have a higher doping concentration than the extension layer immediately below, while having a lower doping concentration than the extension layer immediately above. Also, within each such extension layer of the multilayer extension structure, the doping concentration can be uniformly distributed. For example, multilayer (e.g., 2, 3, etc., layers) extension structure of FIG. 8B can be formed by repeatedly growing extensions (e.g., epitaxially) on semiconductor substrate 100.

During the extension growth procedure, the concentration distribution of the dopant in each extension layer can be uniform at a same horizontal plane, while sequentially increasing from bottom to top in the vertical (y) direction. As shown in FIGS. 8A and 8B, if the dopant concentration at the top and bottom surfaces of the extension structure is C_{N-top} and C_{N-bottom}, respectively, the extension structure can have a sloped concentration and a concentration gradient. This can result in the top dopant concentration of the extension structure being greater than the bottom dopant concentration (e.g., C_{N-top}>C_{N-bottom}) in either case.

Referring back to FIG. 7, at S23, etching can be performed from the top of the extension structure to semiconductor substrate 100. The etching process can chemically remove layers or portions of layers from the surface of a wafer during manufacturing. For many etch steps, part of the wafer can be protected from the etchant by a “masking” material (e.g., patterned photoresist, silicon nitride, etc.) that resists etching. Any suitable type of etching (e.g., wet etching, dry etching, plasma etching, etc.) can be employed to form the trenches in particular embodiments.

Etching in particular embodiments can be used form a mutually spaced inverted trapezoidal trench structure in extension structure 200. During the trench etching procedure, the sidewall of the inverted trapezoidal trench structure may have a trench bevel θ, or beveled edge as to the horizontal direction. For example, θ can be from about 87° to about 89°, to guarantee that the filler can be successfully (e.g., fully) filled in the trench. Of course, other beveled edge angles (e.g., 80°, 85°, 90°, 95°, etc.) can also be supported in particular embodiments, and as may be appropriate for the particular materials of the filler and extension structure 200. In any event, the trench sidewalls can form sides of an inverted trapezoidal structure with broader shape at the top (e.g., yn) and a narrowing at the bottom (e.g., y0).

In FIG. 7, at S24, the filler with dopant can be injected into the inverted trapezoidal trench structure to form doped pillar regions 300. Also, the portion of extension structure 200 between doped pillar regions 300 can be configured as doped pillar region 400. This is the portion that may have a doping concentration that sequentially increases from bottom (e.g., y0) to top (e.g., yn) of the structure. As shown in FIG. 5, doped pillar regions 300 can be mutually spaced regions, so as to alternately arrange doped pillar regions 300 and doped pillar region 400 in the horizontal direction. In addition, adjacent doped pillar regions 300 and doped pillar region 400 can form a super-junction structure.

The dopant type of the filler can be opposite to that of doped pillar region 400. In this example, the dopant of doped pillar region 400 can be n-type (forming n-extension), while the dopant of doped pillar region 300 can be p-type (forming a P pillar). Alternatively, when the dopant of doped pillar region 400 is p-type (forming p-extension), n-type dopant can be injected into the trench to form an N pillar as doped pillar region 300.

Because each of doped pillar regions 300 form an inverted trapezoidal structure, the doping concentration of doped pillar regions 300 can increase from bottom to top. In this way, charge-balance of doped pillar region 400 and doped pillar regions 300 can be achieved at each “y” position from bottom (y0) to top (yn). The dopant slope concentration distribution of doped pillar region 400 may satisfy C_{P}W_{P(yn)}=C_{N}W_{N (yn)}. For example, C_{P} and C_{N} can respectively represent the doping concentration of doped pillar regions 300 and doped pillar region 400, while W_{P} and W_{N} can respectively represent the widths of the pillars corresponding to the doping concentration.

As the doping concentration of doped pillar region 400 sequentially increases from bottom to top (e.g., by regulating the doping concentration gradient of doped pillar region 400, as shown in FIG. 8A or 8B), doped pillar region 400 and doped pillar regions 300 can have a same charge at a same “y” position. This can achieve charge-balance of doped pillar regions 300 and doped pillar region 400 in the super-junction at every depth. In this way, a higher breakdown voltage can be obtained for the power device for a given doping concentration.

In particular embodiments, a semiconductor device can include semiconductor substrate 100 and extension structure 200, where extension structure 200 is located on semiconductor substrate 100. The doping concentration of extension structure 200 can sequentially increase from bottom to top in the vertical direction. Also, doped pillar regions 300 can be formed in extension structure 200, and portions of extension structure 200 between doped pillar regions 300 may be configured as doped pillar region 400.

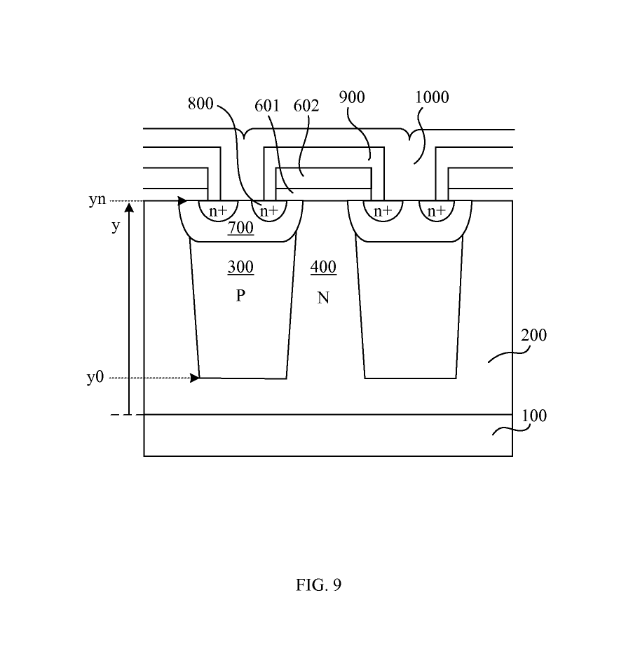

Referring now to FIG. 9, shown is a diagram of another example semiconductor device in accordance with embodiments of the present invention. Gate oxide layer 601 can be formed on doped pillar region 400. For example, before forming gate oxide layers 601, the filler in doped pillar regions 300 can be planarized on the horizontal surface (e.g., at yn), in order to maintain the surfaces of doped pillar regions 300 and 400 at the same level. Gate 602 (e.g., polysilicon) can then be formed on gate oxide layer 601. Gate 602 can be etched to expose a surface of doped pillar regions 300 to form an opening. For example, the horizontal width of the opening in gate 602 can be less than or equal to the horizontal width at the upper surface (e.g., at yn) of the trench.

Gate 602 can be used as a mask layer, and p-type ion impurities can be injected into the upper region of doped pillar regions 300 at the opening in the gate where. This impurity injection can form base layers 700 at the upper region of doped pillar regions 300 and extending at least partially under gate 602. Thus, portions of gate 602 and base layers 700 can overlap. Also, n-type dopant can be injected into base layers 700 to form at least one source region 800 in base layer 700. Source regions 800 can be high concentration n-type (n+) impurity regions, and two source regions 800 can be formed in one base layer 700 in this example.

A metal layer can be deposited on the surface of base layers 700, gate oxide layers 601, and gates 602. The metal layer (e.g., aluminum) can be etched to form source electrode 900. Also, contact holes or via openings can be formed through photolithography processes to expose the upper surface of base layers 700 that includes source regions 800. In this way, electrical connection can be formed between source electrodes 900 and at least one of source regions 800 in base layers 700. Further, oxide (e.g., silicon oxide) layer 1000 can be formed on the surface of source electrodes 900 and base layers 700.

Therefore, gate oxide layers 601 can be formed on doped pillar region 400, and gates 602 can be formed on gate oxide layers 601. Base layers 700 can be formed on the upper regions of doped pillar regions 300, and at least one source regions 800 can be formed in each base layer 700. Source electrodes 900 can be formed on a surface of base layers 700, gate oxide layers 601 and gates 602. Source electrodes 900 can be electrically connected to at least one of source regions 800 of base layers 700. Oxide layer 1000 formed on a surface of source electrodes 900 and base layers 700. For example, base layers 700 can be formed at two sides of gates 602, and portions of gates 602 and base layers 700 may overlap.

Certain embodiments can also provide a power device (e.g., a power transistor) that utilizes a process and/or is fabricated in a wafer structure, as described herein. Any such power device (e.g., a super-junction MOSFET, an insulated gate bipolar transistor [IGBT], a vertical double diffused metal oxide semiconductor [VDMOS] transistor, a diode, etc.) can be employed in particular embodiments, and may be included in a switching voltage regulator or switched-mode power supply (SMPS).

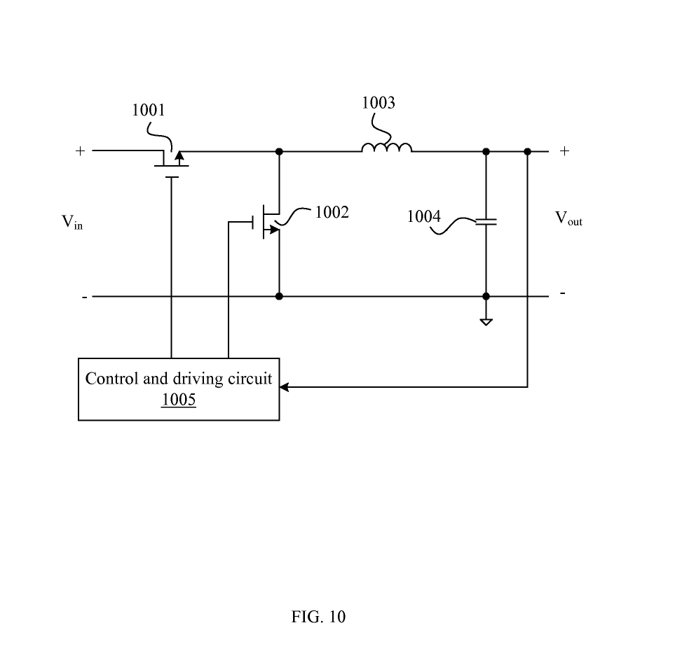

Referring now to FIG. 10, shown is a schematic diagram of an example switching voltage regulator that includes power devices as described herein. A switching voltage regulator is just one example of the circuitry that can be wholly or partially fabricated in the wafer structure and/or using processes of particular embodiments. In this example, power transistors 1001 and 1002, inductor 1003, and capacitor 1004 can form a synchronous buck power stage circuit. In other cases, other types of power stage or converter circuits (e.g., flyback, SEPIC, boost, buck-boost, etc.) can be formed. Control and driving circuit 1005 (e.g., including a pulse-width modulation [PWM] controller) can receive an output signal of the power stage circuit, to form a closed-loop feedback control loop to control the switching state of power transistors 1001 and 1002. In this way, the output signal of the power stage circuit can be controlled to be substantially constant.

Of course, other integration or grouping of circuitry into different chips, ICs, or wafers can be accommodated in particular embodiments. In one example, a multi-chip packaging structure in particular embodiments can include power transistors 1001 and 1002 being integrated into a power device chip, and control and driving circuit 1005 being integrated into a control chip. Since the power device may process a high voltage and/or a high current, the power device chip with a large area can be able to withstand a relatively high voltage and a relatively high current. Also, the power device may have good thermal characteristics for power supply integration.

For the integrated circuit of the switching voltage regulator shown in FIG. 10, if the carrying capacity of power transistor 1002 is greater than that of power transistor 1001, power transistor 1002 may be much larger than power transistor 1001. Thus, power transistor 1002 (e.g., the synchronous power device) can be integrated in a single synchronous power device chip, and power transistor 1001 (e.g., the main power device) as well as control and driving circuit 1005 can be integrated in another single mixed chip. Further, power transistors 1001 and/or 1002 can be any suitable types of transistors or devices (e.g., super-junction MOS transistors, VDMOS, LDMOS, IGBT, etc.)

The embodiments were chosen and described in order to best explain the principles of the invention and its practical applications, to thereby enable others skilled in the art to best utilize the invention and various embodiments with modifications as are suited to the particular use contemplated. It is intended that the scope of the invention be defined by the claims appended hereto and their equivalents.

What is claimed is:

1. A semiconductor device, comprising:
a) a first doped pillar region having a doping concentration that sequentially increases from bottom to top in a vertical direction;
b) second doped pillar regions arranged on either side of said first doped pillar region in a horizontal direction; and
c) wherein sidewalls of said second doped pillar regions form sides of an inverted trapezoidal structure.

2. The semiconductor device of claim 1, further comprising:
a) a semiconductor substrate;
b) an extension structure on said semiconductor substrate, wherein a doping concentration of said extension structure sequentially increases from bottom to top in said vertical direction; and
c) wherein said second doped pillar regions are formed in said extension structure, and a portion of said extension structure that is between said second doped pillar regions is configured as said first doped pillar region.

3. The semiconductor device of claim 2, wherein said extension structure comprises a monolayer structure, and a doping concentration of said extension structure sequentially increases from bottom to top of said trapezoidal structure.

4. The semiconductor device of claim 2, wherein said extension structure comprises at least two extension layers, and a doping concentration of each of said at least two extension layers is uniform distributed and sequentially increases from bottom to top.

5. The semiconductor device of claim 1, wherein said second doped pillar regions and said first doped pillar region form a horizontal surface structure selected from a strip structure, a circular structure, and a cellular structure.

6. The semiconductor device of claim 5, wherein in said cellular structure, said first doped pillar structure surrounds said second doped pillar structures.

7. A method of making a semiconductor device, the method comprising:
a) forming a first doped pillar region having a doping concentration that sequentially increases from bottom to top in a vertical direction;
b) forming an inverted trapezoidal trench structure; and
c) forming second doped pillar regions by injecting filler with dopant into said inverted trapezoidal trench structure, wherein said first doped pillar region and said second doped pillar regions are alternately arranged in a horizontal direction.

8. The method of claim 7, further comprising:
a) providing a semiconductor substrate;
b) growing an extension structure on said semiconductor substrate, wherein a doping concentration of said extension structure sequentially increases from bottom to top; and
c) etching from a top of said extension structure to said semiconductor substrate to form said inverted trapezoidal trench structure in said extension structure, wherein a portion of said extension structure between said second doped pillar regions is configured as said first doped pillar region.

9. The method of claim 8, wherein said extension structure comprises a monolayer structure, and a doping concentration of said extension structure sequentially increases from bottom to top of said trapezoidal structure.

10. The method of claim 8, wherein said extension structure comprises at least two extension layers, and a doping concentration of each of said at least two extension layers is uniform distributed and sequentially increases from bottom to top.

11. The method of claim 7, wherein said second doped pillar regions and said first doped pillar region form a horizontal surface structure selected from a strip structure, a circular structure, and a cellular structure.

12. The method of claim 11, wherein in said cellular structure, said first doped pillar structure surrounds said second doped pillar structures.
